(19) United States
(12) Patent Application Publication
(10) Pub. No.: US 2022/0224081 A1
(43) Pub. Date: Jul. 14, 2022

(54) SURFACE-EMITTING LASER

(71) Applicant: Phosertek Corporation, Hsinchu City (TW)

(72) Inventors: Chien-Ping Lee, Hsinchu City (TW); Kuo-Jui Lin, Taichung City (TW); Chien-Hung Lin, Hsinchu City (TW); Bo-Tsun Chou, Hsinchu City (TW)

(73) Assignee: Phosertek Corporation, Hsinchu City (TW)

(21) Appl. No.: 17/573,636

(22) Filed: Jan. 12, 2022

Related U.S. Application Data
(60) Provisional application No. 63/136,206, filed on Jan. 12, 2021.
(60) Provisional application No. 63/143,927, filed on Jan. 31, 2021.

(51) Int. Cl. H01S 5/183; H01S 5/042

(52) U.S. Cl. CPC H01S 5/18361; H01S 5/18394; H01S 5/18305; H01S 5/04256

(57) ABSTRACT

A surface-emitting laser including a cladding layer, an active region, a first grating, a plurality of second gratings, a first electrode, and a second electrode is provided. The active region is disposed on the cladding layer. The first grating is disposed on the active region. The second gratings are disposed on the active region and separately distributed among the first grating. A diffraction order of the first grating is different from a diffraction order of the second gratings. The first electrode is electrically connected to the cladding layer. The second electrode covers at least the first grating.

### CROSS-REFERENCE TO RELATED APPLICATION

This application claims the priority benefit of U.S. Provisional Application No. 63/136,206, filed on Jan. 12, 2021, and U.S. Provisional Application No. 63/143,927, filed on Jan. 31, 2021. The entirety of each of the above-mentioned patent applications is hereby incorporated by reference herein and made a part of this specification.

### BACKGROUND OF THE INVENTION

### 1. Field of the Invention

The invention generally relates to a light-emitting device and, in particular, to a surface-emitting laser.

### 2. Description of Related Art

A semiconductor laser can be classified into a surface-emitting laser and an edge-emitting laser. The surface-emitting laser has various types, including a vertical cavity surface-emitting laser (VCSEL), a photonic crystal surface-emitting laser, a distributed feedback surface-emitting laser, etc.

In a distributed laser, a grating and reflection are generally continuous along a resonance cavity, instead of just being at two opposite ends of the resonance cavity. This changes the modal behavior considerably and makes the laser more stable.

However, for a distributed feedback surface-emitting laser or a photonic crystal surface-emitting laser, a metal electrode at the light-emitting side of the laser has an opening for light output, so that current is not spread uniformly in an active region below the opening and current crowding effect is thus formed. Therefore, the beam quality and beam control of the laser are adversely affected.

### SUMMARY OF THE INVENTION

Accordingly, the invention is directed to a surface-emitting laser, which has good current spreading, good beam quality, and good beam control.

An embodiment of the invention provides a surface-emitting laser including a cladding layer, an active region, a first grating, a plurality of second gratings, a first electrode, and a second electrode. The active region is disposed on the cladding layer. The first grating is disposed on the active region. The second gratings are disposed on the active region and separately distributed among the first grating. A diffraction order of the first grating is different from a diffraction order of the second gratings. The first electrode is electrically connected to the cladding layer. The second electrode covers at least the first grating.

In the surface-emitting laser according to the embodiment of the invention, since the second gratings are separately distributed among the first grating, the first grating is used for laser feedback for more efficient reflection of the light emitted by the active region, and the second gratings are used for output coupling by diffraction. Therefore, the laser characteristics of the surface-emitting laser are better controlled. As a result, the surface-emitting laser has good beam quality and good beam control. Moreover, in the surface-emitting laser according to the embodiment of the invention, the second electrode covers at least the first grating, so that the surface-emitting laser has good and uniform current spreading, and current crowding effect is effectively reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic perspective view of a surface-emitting laser according to an embodiment of the invention.

FIG. 1B is a schematic cross-sectional view of the surface-emitting laser in FIG. 1A.

FIG. 2A, FIG. 2B, and FIG. 2C are schematic local top views of three embodiments of the first grating and the second gratings of the surface-emitting laser in FIG. 1B.

FIG. 3A, FIG. 3B, and FIG. 3C are schematic local cross-sectional views of three embodiments of the first grating and the second gratings of the surface-emitting laser in FIG. 1B.

FIG. 4 is a schematic cross-sectional view of the surface-emitting laser according to another embodiment of the invention.

FIG. 5 is a schematic cross-sectional view of the surface-emitting laser according to another embodiment of the invention.

FIG. 6 is a schematic cross-sectional view of the surface-emitting laser according to another embodiment of the invention.

FIG. 7 is a schematic cross-sectional view of the surface-emitting laser according to another embodiment of the invention.

FIG. 8 is a schematic cross-sectional view of the surface-emitting laser according to another embodiment of the invention.

FIG. 9 is a schematic view showing light spots of the sub-beams and the openings of the surface-emitting laser in FIG. 1A and FIG. 1B respectively in a far-field and a near-field.

FIG. 10 is a schematic top transparent view of the surface-emitting laser showing the second electrode, the first grating, and the second gratings according to another embodiment of the invention.

FIG. 11A is a schematic top transparent view of the surface-emitting laser showing the second electrode and the second gratings according to another embodiment of the invention.

FIG. 11B is a perspective view of the surface-emitting laser in FIG. 11A showing different sub-beams due to different sub-electrodes.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

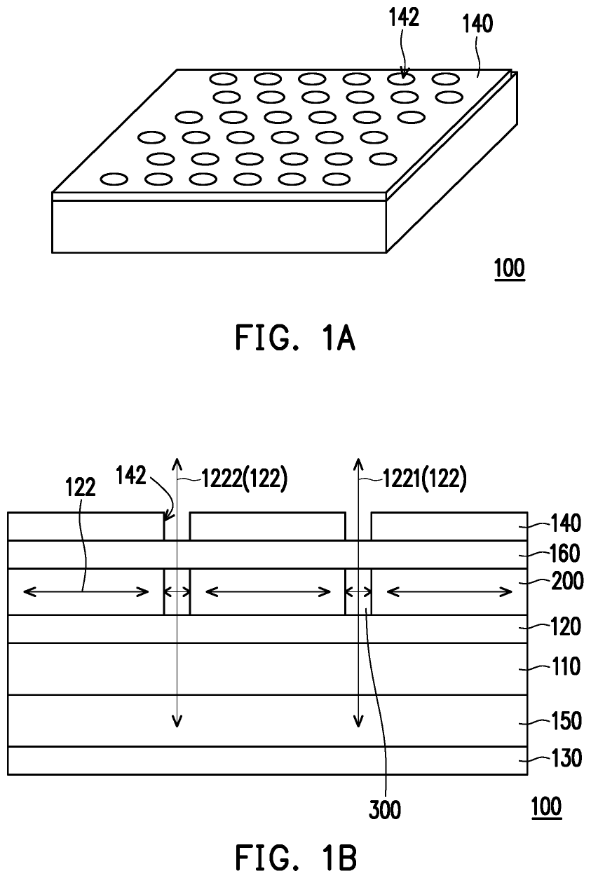

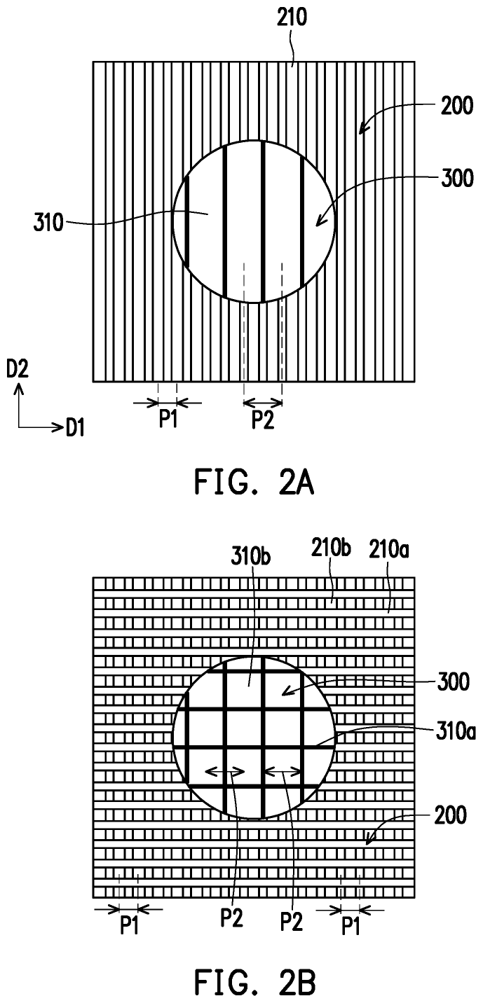

FIG. 1A is a schematic perspective view of a surface-emitting laser according to an embodiment of the invention, and FIG. 1B is a schematic cross-sectional view of the surface-emitting laser in FIG. 1A. Referring to FIG. 1A and FIG. 1B, the surface-emitting laser 100 in this embodiment includes a cladding layer 110, an active region 120, a first grating 200, a plurality of second gratings 300, a first electrode 130, and a second electrode 140. The active region 120 is disposed on the cladding layer 110. The first grating 200 is disposed on the active region 120. The second gratings 300 are disposed on the active region 120 and separately distributed among the first grating 200. A diffraction order of the first grating 200 is different from a diffraction order of the second gratings 300. The first electrode 130 is electrically connected to the cladding layer 110. The second electrode 140 covers at least the first grating 200.

In this embodiment, the second electrode 140 covers the first grating 200 and has a plurality of openings 142 above the second gratings 200. The second electrode 140 is, for example, a metal electrode layer. Moreover, the diffraction order of the first grating 200 is greater than or equal to 1, and the diffraction order of the second gratings 300 is greater than or equal to 2. In this embodiment, the first grating 200 is a first order grating, and the second gratings 300 are second order gratings. When the first electrode 130 and the second electrode 140 are applied with a forward voltage, the active region 120 emits light 122. The first grating 200 transmits and reflects the light 122 in a horizontal direction parallel to the active region 120 to form distributed feedback, i.e. laser feedback. The second gratings 300 diffracts the light 122 in a vertical direction perpendicular to the active region to form output coupling. The light 122 diffracted by the second gratings 300 passes through the openings 142 to travel out of the surface-emitting laser 100. In other embodiments, when the second gratings 300 are third order gratings, the second gratings 300 diffract the light 122 along inclined directions. For example, the inclined directions and a normal direction of the active region 120 have an included angle of 60 degrees. When the diffraction order of the second gratings 300 is greater than or equal to 4, the second gratings 300 have other different inclined directions.

In the surface-emitting laser 100, the laser feedback and output coupling are separated for better control of laser characteristics. The first grating 200 (i.e. the first order grating) is used for distributed feedback for more efficient reflection, and the second gratings 300 (i.e. the second order grating) is used below the openings 142 (i.e. output windows) for output coupling. Therefore, the surface-emitting laser 100 has good beam quality and good beam control. Moreover, the second electrode 140 (i.e. a metal electrode layer) covers the first grating 200, so that current can be spread horizontally and uniformly in the second electrode 140. As a result, the surface-emitting laser 100 has good and uniform current spreading, and current crowding effect is effectively reduced.

In this embodiment, the surface-emitting laser 100 further includes a substrate 150 disposed between the cladding layer 110 and the first electrode 130. The first electrode 130 is, for example, a metal electrode layer covering a bottom surface of the substrate 150. In this embodiment, the surface-emitting laser 100 further includes a contact layer 160 disposed between the first grating 200 and the second electrode 140 and covers the second gratings 300. The contact layer 160 form good electrical contact for the first grating 200 and the second electrode 140.

In this embodiment, the cladding layer 110 is an n-type semiconductor layer, and the first grating 200 and the second gratings 300 form a p-type semiconductor layer. However, in other embodiments, the cladding layer 110 is a p-type semiconductor layer, and the first grating 200 and the second gratings 300 form an n-type semiconductor layer.

In this embodiment, the second gratings 300 diffract light 122 emitted by the active region 120 into a plurality of sub-beams (e.g. the sub-beams 1221 and 1222 shown in FIG. 1B) traveling out of the surface-emitting laser 100, and adjacent sub-beams 1221 and 1222 interfere with each other. For example, the sub-beam 1221 and the sub-beam 1222 may form constructive interference, so as to form a light spot in a far-field having good beam quality. The first grating 200 transmits and strongly couples light 122 between the second gratings 300 so as to ensure the coherence between the sub-beams.

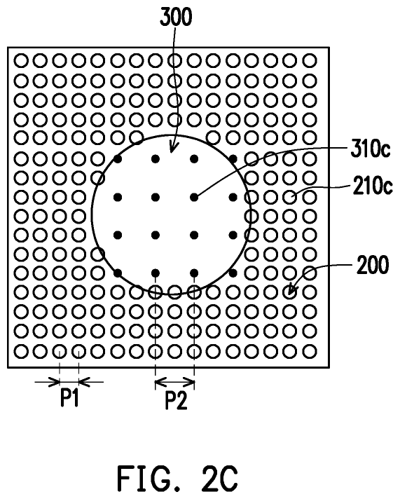

FIG. 2A, FIG. 2B, and FIG. 2C are schematic local top views of three embodiments of the first grating and the second gratings of the surface-emitting laser in FIG. 1B. Referring to FIG. 1B and FIG. 2A first, in this embodiment, the first grating 200 and the second gratings 300 are one-dimensional gratings. In this embodiment, each of the first grating 200 and the second gratings 300 includes a plurality of straight strips 210, 310 parallel to each other. Specifically, the first grating 200 includes a plurality of straight strips 210 arranged in a first direction D1, and the second grating 300 includes a plurality of straight strips 310 arranged in the first direction D1. Each of the straight strips 210 extends along a second direction D2, and Each of the straight strips 310 extends along the second direction D2. The first direction D1 may be perpendicular to the second direction D2. In this embodiment, a pitch P2 of the straight strips 310 of the second gratings 300 is greater than a pitch P1 of the straight strips 210 of the first grating 200.

Referring to FIG. 1B and FIG. 2B, in this embodiment, the first grating 200 and the second gratings 300 are two-dimensional gratings. Each of the first grating 200 and the second gratings 300 includes two-dimensional line array or two-dimensional pillar array. Specifically, the first grating 200 may include two-dimensional line array 210a, and the second gratings 300 may include two-dimensional line array 310a. Alternatively, in another embodiment, the first grating 200 may include two-dimensional pillar array 210b, and the second gratings 300 may include two-dimensional pillar array 310b. In other embodiments, Each of the first grating 200 and the second gratings 300 may include two-dimensional polygon array.

Referring to FIG. 1B and FIG. 2C, in this embodiment, each of the first grating 200 and the second gratings 300 includes two-dimensional hole array. Specifically, the first grating 200 includes two-dimensional hole array 210c, and the second grating 300 includes two-dimensional hole array 310c.

In FIG. 2A, FIG. 2B, and FIG. 2C, a pitch P2 of the two-dimensional hole, line, or pillar array 310c, 210a, 210b of the second gratings 300 is greater than a pitch P1 of the two-dimensional hole, line, or pillar array 210c, 210a, 210b of the first grating 200.

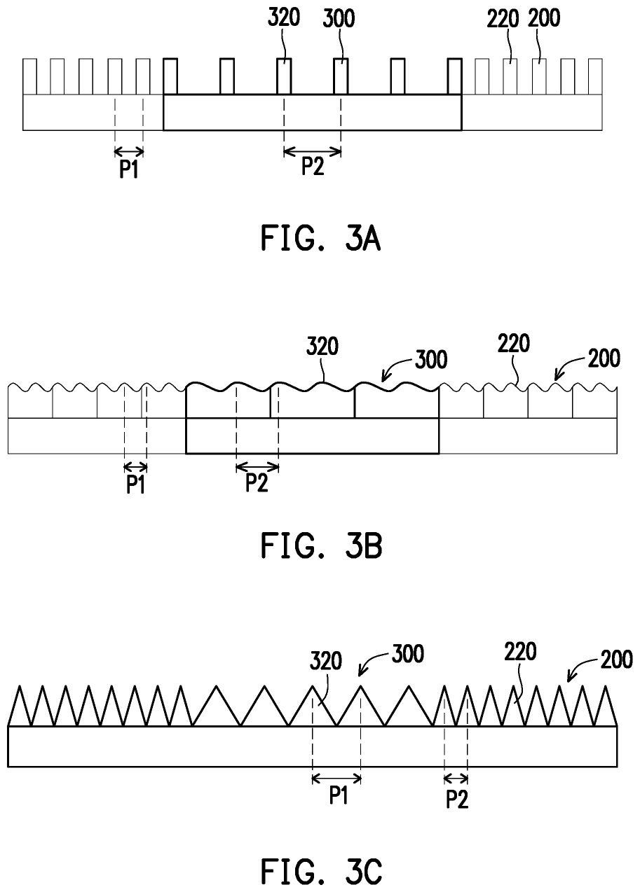

FIG. 3A, FIG. 3B, and FIG. 3C are schematic local cross-sectional views of three embodiments of the first grating and the second gratings of the surface-emitting laser in FIG. 1B. Referring to FIG. 1B, FIG. 3A, FIG. 3B, and FIG. 3C, each of the first grating 200 and the second gratings 300 includes a plurality of periodical units periodically arranged. Specifically, the first grating 200 includes a plurality of periodical units 220 periodically arranged, and the second grating 300 includes a plurality of periodical units 320 periodically arranged. A profile of each of the periodical units 220 and 320 in a cross-section perpendicular to the active region 120 is a step shape (as shown in FIG. 3A), a wave shape (as shown in FIG. 3B), or a triangular shape (as shown in FIG. 3C). In these embodiments, a pitch P2 of the periodical units 320 of the second gratings 300 is greater than a pitch P1 of the periodical units 220 of the first grating 200.

In this embodiment, the material of the substrate includes gallium nitride (GaN), gallium arsenide (GaAs), indium phosphide (InP), gallium antimonide (GaSb), indium arsenide (InAs), sapphire, any other suitable material, or a combination thereof. The material of the cladding layer 110 may include GaN, aluminum gallium arsenide (AlGaAs), aluminum gallium arsenic antimonide (AlGaAsSb), any other suitable material, or a combination thereof. The active region 120 may have quantum structure, for example, quantum wells, quantum dots, etc. The material of the active region 120 may include indium arsenide (InAs) and gallium arsenide (GaAs); indium gallium arsenide (InGaAs) and gallium aluminum arsenide (GaAlAs); indium gallium arsenic antimonide (InGaAsSb) and aluminum gallium arsenic antimonide (AlGaAsSb); indium gallium nitride (InGaN) and gallium nitride (GaN); indium gallium nitride (InGaN) and gallium aluminum nitride (GaAlN); indium arsenide (InAs) and indium phosphide (InP); indium arsenic antimonide (InAsSb) and indium phosphide (InP); other suitable materials or a combination thereof. The material of the first grating 200 and the second gratings 300 may include GaAs, InP, GaSb, AlGaAs, AlGaAsSb, any other suitable material, or a combination thereof. The material of the contact layer 160 may include GaAs, InP, GaN, GaSb, gallium phosphide (GaP), InAs, AlGaAs, AlGaAsSb, transparent conductive material, any other suitable material, or a combination thereof, wherein the transparent conductive material may include indium tin oxide (ITO), indium zinc oxide (IZO), aluminum doped zinc oxide (AZO), any other suitable material, or a combination thereof.

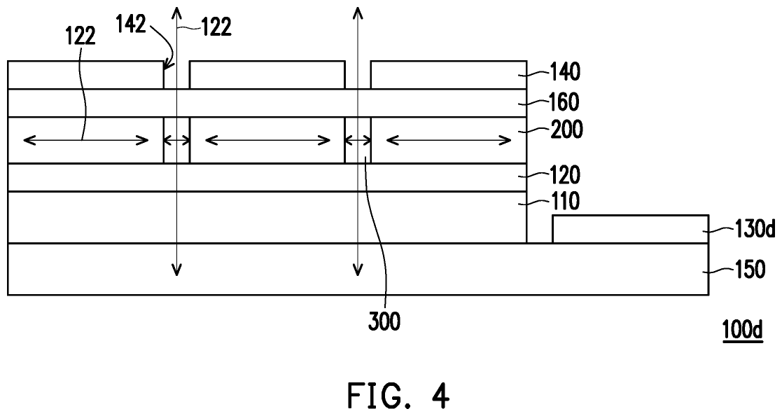

FIG. 4 is a schematic cross-sectional view of the surface-emitting laser according to another embodiment of the invention. Referring to FIG. 4, the surface-emitting laser 100d in this embodiment is similar to the surface-emitting laser 100 in FIG. 1B, and the main difference therebetween is as follows. In the surface-emitting laser 100d according to this embodiment, the cladding layer 110 and the first electrode 130d are disposed on the substrate 150, and the cladding layer 110 and the first electrode 130d are disposed on the same side of the substrate 150.

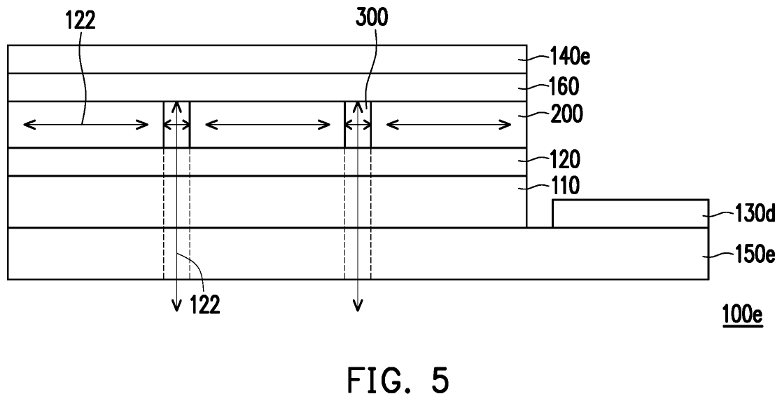

FIG. 5 is a schematic cross-sectional view of the surface-emitting laser according to another embodiment of the invention. Referring to FIG. 5, the surface-emitting laser 100e in this embodiment is similar to the surface-emitting laser 100d in FIG. 4, and the main difference therebetween is as follows. In the surface-emitting laser 100d in FIG. 4, the second gratings 300 diffract the light 122 emitted by the active region 120 to pass through the openings 142, so that the light 122 travels out of the surface-emitting laser 100d through the openings 142. However, in the surface-emitting laser 100e in FIG. 5, the second electrode 140e covers the first grating 200 and the second gratings 300; that is, the second electrode 140e does not have openings 142 as shown in FIG. 4. Moreover, the substrate 150e is pervious to the light 122 emitted by the active region 120. That is to say, the second gratings 300 diffract the light 122 upwards and downwards. The upward light 122 is then reflected by the second electrode 140e (e.g. a metal electrode layer) downwards. The downward light 122 passes through the substrate 150e and then travels out of the surface-emitting laser 100e. Therefore, the surface-emitting laser 100e is a bottom emitting laser.

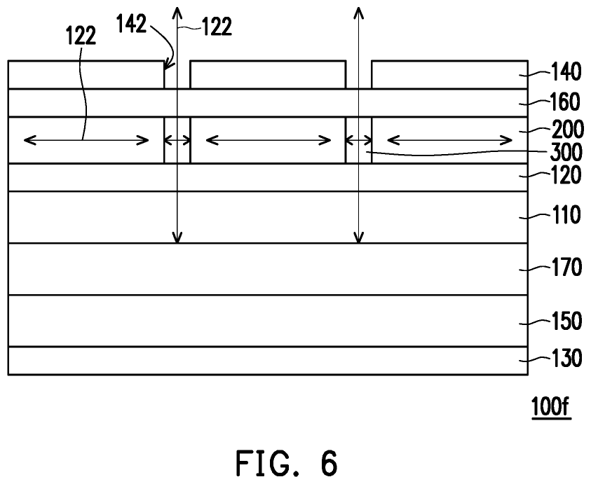

FIG. 6 is a schematic cross-sectional view of the surface-emitting laser according to another embodiment of the invention. Referring to FIG. 6, the surface-emitting laser 100f in this embodiment is similar to the surface-emitting laser 100 in FIG. 1B, and the main difference therebetween is as follows. The surface-emitting laser 100f according to this embodiment further includes a distributed Bragg reflection (DBR) layer 170, wherein the cladding layer 110 is disposed between the active region 120 and the DBR layer 170. In this embodiment, the DBR layer 170 is disposed between the cladding layer 110 and the substrate 150. The second gratings 300 diffract the light 122 upwards and downwards. The downward light 122 is reflected by the DBR layer 170 upwards. The upward light 122 passes through the openings 142 and travels out of the surface-emitting laser 100f. The DBR layer 170 prevents the light 122 from leaking from the bottom of the surface-emitting laser 100f, so that the light efficiency of the surface-emitting laser is improved.

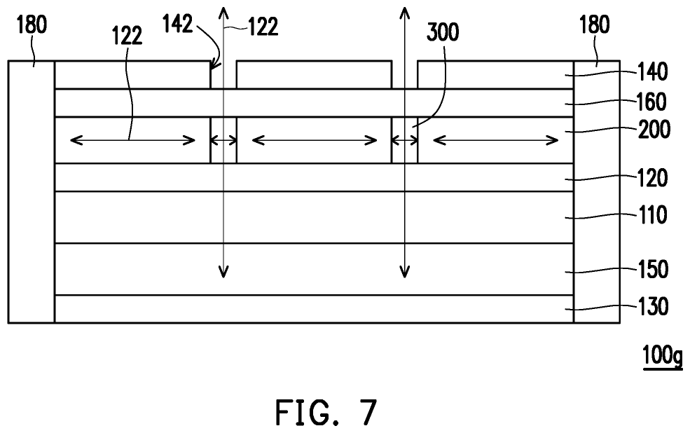

FIG. 7 is a schematic cross-sectional view of the surface-emitting laser according to another embodiment of the invention. Referring to FIG. 7, the surface-emitting laser 100g in this embodiment is similar to the surface-emitting laser 100 in FIG. 1B, and the main difference therebetween is as follows. The surface-emitting laser 100g according to this embodiment further includes a mirror layer 180 disposed on side surfaces of the cladding layer 110, the active region 120, and the first grating 200. In this embodiment, the mirror layer 180 is also disposed on side surfaces of the first electrode 130, the substrate 150, the contact layer 160, and the second electrode 140. When the first grating 200 transmits and reflects the light 122 in a horizontal direction, the mirror layer 180 serves as a facet mirror to reflects the light 122 back to the first grating 200 and prevents the light 122 from leaking out from the side surface of the first grating 200. Therefore, the light efficiency of the surface-emitting laser 100 is improved.

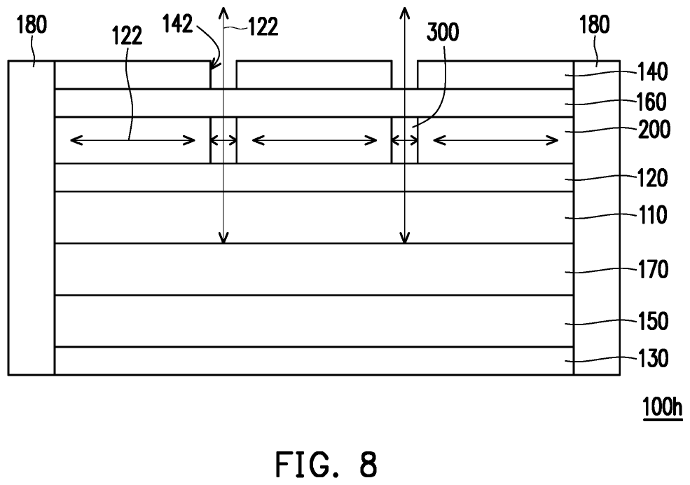

FIG. 8 is a schematic cross-sectional view of the surface-emitting laser according to another embodiment of the invention. Referring to FIG. 8, the surface-emitting laser 100h in this embodiment is similar to the surface-emitting laser 100g in FIG. 7, and the main difference therebetween is as follows. The surface-emitting laser 100h according to this embodiment further includes a DBR layer 170, wherein the cladding layer 110 is disposed between the active region 120 and the DBR layer 170. In this embodiment, the DBR layer 170 is disposed between the cladding layer 110 and the substrate 150. Besides, in this embodiment, the mirror layer 180 is also disposed on a side surface of the DBR layer 170.

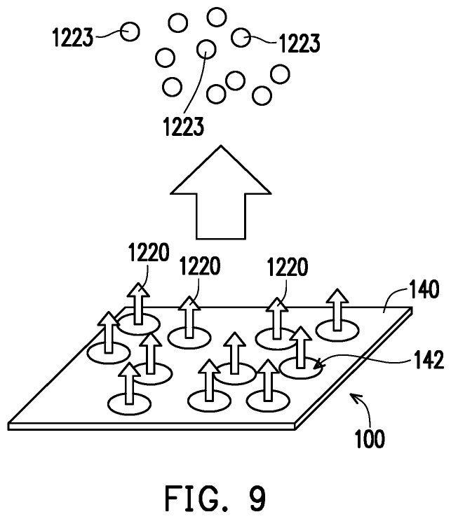

FIG. 9 is a schematic view showing light spots of the sub-beams and the openings of the surface-emitting laser in FIG. 1A and FIG. 1B respectively in a far-field and a near-field. Referring to FIG. 1B and FIG. 9, in the surface-emitting laser 100, the openings 142 may be in an order arrangement or in a random arrangement. The second gratings 300 diffract the light 122 emitted by the active region 120 into a plurality of sub-beams 1220. The sub-beams 1220 pass through the openings 142 in the near-field, respectively, and travel out of the surface-emitting laser 100 to the far-field, so as to form a plurality of light spots 1223 in the far-field, respectively. According to the pattern design of the openings 142 in the near-field and the diffraction order of the second gratings 300, the pattern of the light spots 1223 in the far-field may be designed. Sub-beams 1220 from adjacent openings 142 may interfere with each other to form beam shaping so as to form a different light spot pattern in the far-field. The pattern of the light spots 1223 may be in an order arrangement, a random arrangement. In another embodiment, due to beam shaping, the sub-beams 1220 may form order or random bright lines in the far-field. In another embodiment, multiple sub-beams 1220 interference with properly designed openings 142 arrangement can result very small beam divergence and excellent beam quality.

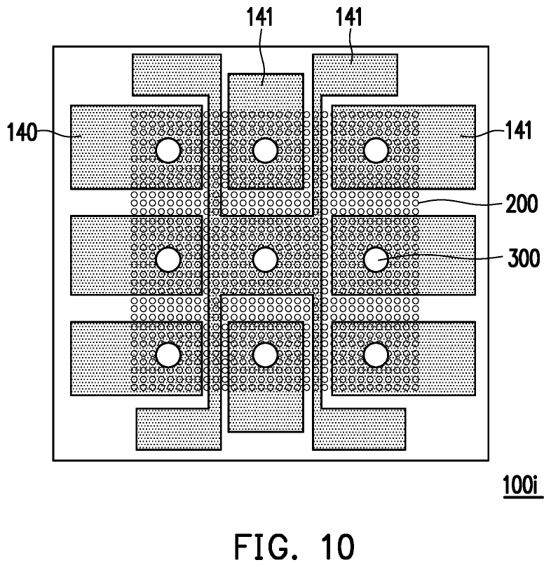

FIG. 10 is a schematic top transparent view of the surface-emitting laser showing the second electrode, the first grating, and the second gratings according to another embodiment of the invention. Referring to FIG. 10, the surface-emitting laser 100i in this embodiment is similar to the surface-emitting laser 100 in FIG. 1A and FIG. 1B, and the main difference therebetween is as follows. In the surface-emitting laser 100i, the second electrode 140 includes a plurality of separate sub-electrodes 141 respectively covering different sets of the second gratings 300, wherein the sub-electrodes 141 are independently driven. In this embodiment, the sub-electrodes 141 may be independently driven by a driver. For example, when the surface-emitting laser 100i needs to emit a light beam to an object in a long distance, all sub-electrodes 141 may be driven, and all second gratings 300 diffract the light 122 into the sub-beams 1220 to form a light beam with high intensity. When the surface-emitting laser 100i needs to emit a light beam to an object in a short distance, one or some of the sub-electrodes may be driven, and the other sub-electrodes may not be driven. For example, the middle one or five second gratings may diffract the light 122 into one sub-beam 1220 or five sub-beams 1220 to form a light beam with lower intensity, which may save the power consumption of the surface-emitting laser 100i. In another embodiment, the diffraction order of the second gratings 300 may be 2, 3 or more, or a combination thereof, so that the light patterns provided by the surface-emitting laser 100i may have more variations. In another embodiment, the first electrode 130 may include a plurality of separate sub-electrodes respectively under different sets of the second gratings 300, wherein the sub-electrodes are independently driven. The surface-emitting laser 100i in this embodiment may achieve flexible application in three-dimensional sensing field, better spatial resolution. Moreover, the sub-beams 1220 may be separately designed for better output coupling and beam control. Additionally, the sub-beams 1220 may be separately turned on for power adjustment or beam steering.

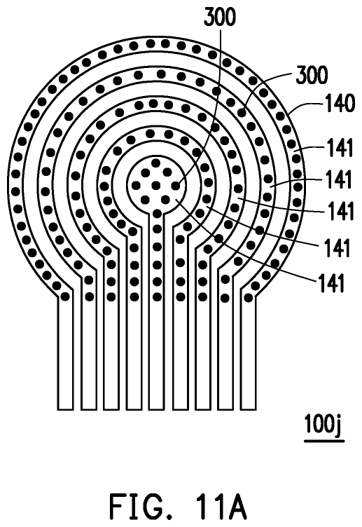

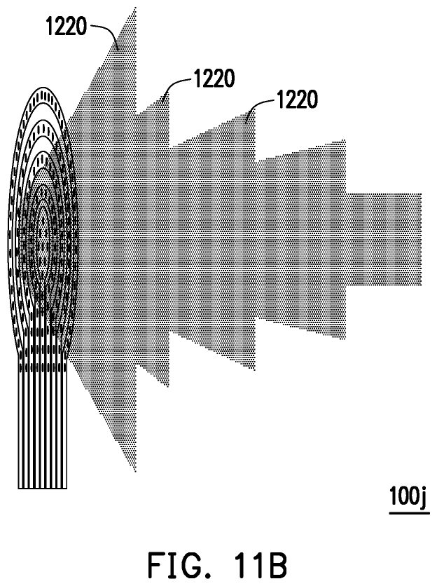

FIG. 11A is a schematic top transparent view of the surface-emitting laser showing the second electrode and the second gratings according to another embodiment of the invention. FIG. 11B is a perspective view of the surface-emitting laser in FIG. 11A showing different sub-beams due to different sub-electrodes. Referring to FIG. 11A and FIG. 11B, the surface-emitting laser 100j in this embodiment is similar to the surface-emitting laser 100i in FIG. 10, and the main difference therebetween is as follows. In the surface-emitting laser 100j, the sub-electrodes 141 are concentrically arranged. Different sub-electrodes 141 may cover different sets of second gratings 300 having different diffraction orders. For example, the set of second gratings 300 covered by the middle sub-electrode 141 may have the second diffraction order, so that the second gratings 300 covered by the middle sub-electrode 141 may emit the sub-beams 1220 in the front direction. The set of second gratings 300 covered by the first inner ring of the sub-electrodes 141 may have the third diffraction order, and emit sub-beams 1220 in a divergent direction. When the sets of second gratings 300 covered by different rings of the sub-electrodes have different diffraction orders, the sets of second gratings 300 may respectively emit sub-beams 1220 with different divergent angle. The sub-electrodes 141 are independently driven. Therefore, by driving one, some, or all of the sub-electrodes 141, the divergent angle of a light beam of the surface-emitting laser 100j may be adjusted. Moreover, when the sub-electrodes 141 are separately turned on, the surface-emitting laser 100i may achieve power adjustment, beam steering, or large angle sweeping.

In conclusion, in the surface-emitting laser according to the embodiments of the invention, since the second gratings are separately distributed among the first grating, the first grating is used for laser feedback for more efficient reflection of the light emitted by the active region, and the second gratings are used for output coupling by diffraction. Therefore, the laser characteristics of the surface-emitting laser are better controlled. As a result, the surface-emitting laser has good beam quality and good beam control. Moreover, in the surface-emitting laser according to the embodiments of the invention, the second electrode covers at least the first grating, so that the surface-emitting laser has good and uniform current spreading, and current crowding effect is effectively reduced.

It will be apparent to those skilled in the art that various modifications and variations can be made to the structure of the invention without departing from the scope or spirit of the invention. In view of the foregoing, it is intended that the invention covers modifications and variations of this invention provided they fall within the scope of the following claims and their equivalents.

What is claimed is:

1. A surface-emitting laser comprising:
a cladding layer;
an active region disposed on the cladding layer;
a first grating disposed on the active region;
a plurality of second gratings disposed on the active region and separately distributed among the first grating, wherein a diffraction order of the first grating is different from a diffraction order of the second gratings;
a first electrode electrically connected to the cladding layer; and
a second electrode covers at least the first grating.

2. The surface-emitting laser according to claim 1, wherein the first grating is a first order grating, and the second gratings are second order gratings.

3. The surface-emitting laser according to claim 1, wherein the second electrode covers the first grating and has a plurality of openings above the second gratings.

4. The surface-emitting laser according to claim 1 further comprising a contact layer disposed between the first grating and the second electrode and covers the second gratings.

5. The surface-emitting laser according to claim 1, wherein the diffraction order of the first grating is greater than or equal to 1, and the diffraction order of the second gratings is greater than or equal to 2.

6. The surface-emitting laser according to claim 1 further comprising a substrate disposed between the cladding layer and the first electrode.

7. The surface-emitting laser according to claim 1 further comprising a substrate, wherein the cladding layer and the first electrode are disposed on a same side of the substrate.

8. The surface-emitting laser according to claim 1 further comprising a substrate, wherein the cladding layer and the first electrode are disposed on the substrate, the second electrode covers the first grating and the second gratings, and the substrate is pervious to light emitted by the active region.

9. The surface-emitting laser according to claim 1 further comprising a mirror layer disposed on side surfaces of the cladding layer, the active region, and the first grating.

10. The surface-emitting laser according to claim 1 further comprising a distributed Bragg reflection layer, wherein the cladding layer is disposed between the active region and the distributed Bragg reflection layer.

11. The surface-emitting laser according to claim 1, wherein the first grating and the second gratings are one-dimensional gratings.

12. The surface-emitting laser according to claim 11, wherein each of the first grating and the second gratings includes a plurality of straight strips parallel to each other.

13. The surface-emitting laser according to claim 12, wherein a pitch of the straight strips of the second gratings is greater than a pitch of the straight strips of the first grating.

14. The surface-emitting laser according to claim 1, wherein the first grating and the second gratings are two-dimensional gratings.

15. The surface-emitting laser according to claim 14, wherein each of the first grating and the second gratings includes two-dimensional hole array, two-dimensional line array, or two-dimensional pillar array.

16. The surface-emitting laser according to claim 15, wherein a pitch of the two-dimensional hole, line, or pillar array of the second gratings is greater than a pitch of the two-dimensional hole, line, or pillar array of the first grating.

17. The surface-emitting laser according to claim 1, wherein each of the first grating and the second gratings includes a plurality of periodical units periodically arranged, and a profile of each of the periodical units in a cross-section perpendicular to the active region is a step shape, a wave shape, or a triangular shape.

18. The surface-emitting laser according to claim 1, wherein each of the first grating and the second gratings includes a plurality of periodical units periodically arranged, a pitch of the periodical units of the second gratings is greater than a pitch of the periodical units of the first grating.

19. The surface-emitting laser according to claim 1, wherein the second gratings diffract light emitted by the active region into a plurality of sub-beams traveling out of the surface-emitting laser, and adjacent sub-beams interfere with each other.

20. The surface-emitting laser according to claim 1, wherein the second electrode comprises a plurality of separate sub-electrodes respectively covering different sets of the second gratings, wherein the sub-electrodes are independently driven.

21. The surface-emitting laser according to claim 20, wherein the sub-electrodes are concentrically arranged.

22. The surface-emitting laser according to claim 1, wherein the second electrode is a metal electrode layer.
